(19) United States
(12) Patent Application Publication
(10) Pub. No.: US 2013/0234272 A1
(43) Pub. Date: Sep. 12, 2013

(54) IMAGE-SENSING MODULE

(71) Applicant: CHI-HSING HSU, NEW TAIPEI CITY (TW)

(72) Inventor: CHI-HSING HSU, NEW TAIPEI CITY (TW)

(73) Assignee: AZUREWAVE TECHNOLOGIES, INC., NEW TAIPEI CITY (TW)

(21) Appl. No.: 13/452,009

(22) Filed: Apr. 20, 2012

(30) Foreign Application Priority Data
Mar. 9, 2012 (TW) 101108153

(51) Int. Cl. H01L 27/146; H01L 31/0232

(52) U.S. Cl. 257/432; 257/443; 257/E31.127; 257/E27.13

(57) ABSTRACT

An image-sensing module includes a substrate unit, a light-transmitting unit, an image-sensing unit and a lens unit. The substrate unit includes at least one flexible substrate having at least one through opening. The light-transmitting unit includes at least one light-transmitting element disposed on the top surface of the flexible substrate and corresponding to the through opening. The image-sensing unit includes at least one image-sensing element disposed on the bottom surface of the light-transmitting element and embedded in the through opening, and the image-sensing element is electrically connected to the flexible substrate. The lens unit includes an opaque frame disposed on the top surface of the flexible substrate to surround the light-transmitting element and a lens positioned on the opaque frame to correspond to the light-transmitting element.

### BACKGROUND OF THE INVENTION

1. Field of the Invention

The instant disclosure relates to an image-sensing module, and more particularly, to an image-sensing module for reducing its whole thickness.

2. Description of Related Art

The advantage of CMOS (Complementary Metal-Oxide-Semiconductor) is low power consumption and small size, thus the CMOS image-sensing chip package module can integrate into portable electronic device with small size such as mobile phone and notebook.

Referring to FIG. 1A to FIG. 1C, the prior art provides an image-sensing module, including: a hard substrate 1a, an image sensor 2a, a plurality of electronic elements 3a, an anti-EMI (Electromagnetic Interference) element 4a, and a USB connector 5a. The image sensor 2a and the electronic elements 3a are electrically connected to the hard substrate 1a. The image sensor 2a is exposed from the first opening 40a of the anti-EMI element 4a, and the hard substrate 1a and the electronic elements 3a are encircled by the anti-EMI element 4a. Hence, the thickness h1 of the hard substrate 1a and the thickness h2 of the anti-EMI element 4a cannot be reduced, thus the whole thickness of the image-sensing module of the prior art cannot be reduced.

### SUMMARY OF THE INVENTION

One aspect of the instant disclosure relates to an image-sensing module for reducing the thickness and avoiding the electromagnetic interference.

One of the embodiments of the instant disclosure provides an image-sensing module, comprising: a substrate unit, a light-transmitting unit, an image-sensing unit and a lens unit. The substrate unit includes at least one flexible substrate, wherein the at least one flexible substrate has at least one through opening. The light-transmitting unit includes at least one light-transmitting element disposed on the top surface of the at least one flexible substrate and corresponding to the at least one through opening. The image-sensing unit includes at least one image-sensing element disposed on the bottom surface of the at least one light-transmitting element and embedded in the at least one through opening, wherein the at least one image-sensing element is electrically connected to the at least one flexible substrate. The lens unit includes an opaque frame disposed on the top surface of the at least one flexible substrate to surround the at least one light-transmitting element and a lens positioned on the opaque frame to correspond to the at least one light-transmitting element.

Furthermore, the at least one flexible substrate has a main portion and at least two extending portions extended upwardly from two opposite lateral sides of the main portion, and the at least two extending portions are respectively close to two opposite lateral sides of the lens unit. The substrate unit includes a plurality of electronic elements disposed on the at least one flexible substrate, and two of the electronic elements are electrically connected to each other through a first conductive track disposed on the main portion, or the substrate unit includes a plurality of electronic elements disposed on the at least one flexible substrate, and two of the electronic elements are electrically connected to each other through a first conductive track simultaneously disposed on the main portion and one of the at least two extending portions.

Moreover, the image-sensing module further comprises a conductive unit including a plurality of first conductive bodies disposed between the at least one light-transmitting element and the at least one flexible substrate and a plurality of second conductive bodies disposed between the at least one light-transmitting element and the at least one image-sensing element. The at least one flexible substrate has at least one first conductive track disposed on the top surface thereof, the at least one light-transmitting element has at least one second conductive track disposed on the bottom surface thereof and electrically connected to the at least one first conductive track through one of the first conductive bodies, and the at least one image-sensing element has at least one third conductive track disposed on the top surface thereof and electrically connected to the at least one second conductive track through one of the second conductive bodies.

In addition, the image-sensing module further comprises a connection unit including a plurality of connection elements disposed between the at least one light-transmitting element and the at least one image-sensing element. The bottom surface of the at least one flexible substrate are flushed with the bottom surface of the at least one image-sensing element.

Another one of the embodiments of the instant disclosure provides an image-sensing module, comprising: a substrate unit, a light-transmitting unit and an image-sensing unit. The substrate unit includes at least one flexible substrate, wherein the at least one flexible substrate has at least one through opening. The light-transmitting unit includes at least one light-transmitting element disposed on the top surface of the at least one flexible substrate and corresponding to the at least one through opening. The image-sensing unit includes at least one image-sensing element disposed on the bottom surface of the at least one light-transmitting element and embedded in the at least one through opening, wherein the at least one image-sensing element is electrically connected to the at least one flexible substrate.

Yet another one of the embodiments of the instant disclosure provides an image-sensing module, comprising: a substrate unit, a light-transmitting unit and an image-sensing unit. The substrate unit includes at least one flexible substrate, wherein the at least one flexible substrate has at least one through opening, and the at least one flexible substrate has at least one first conductive track disposed on the top surface thereof The light-transmitting unit includes at least one light-transmitting element disposed on the top surface of the at least one flexible substrate and corresponding to the at least one through opening, wherein the at least one light-transmitting element has at least one second conductive track disposed on the bottom surface thereof and electrically connected to the at least one first conductive track through a first conductive body. The image-sensing unit includes at least one image-sensing element disposed on the bottom surface of the at least one light-transmitting element and embedded in the at least one through opening, wherein the at least one image-sensing element has at least one third conductive track disposed on the top surface thereof and electrically connected to the at least one second conductive track through a second conductive body, thus the at least one image-sensing element is electrically connected to the at least one flexible substrate.

Therefore, because the at least one image-sensing element can be disposed on the bottom surface of the at least one light-transmitting element and embedded in the at least one through opening, the thickness of the image-sensing module can be reduced.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1A is a top, schematic view of the image-sensing module of the prior art;

FIG. 1B is a front, schematic view of the image-sensing module of the prior art;

FIG. 1C is a cross-sectional, schematic view along line 1C-1C of FIG. 1B;

FIG. 2A shows a top, schematic view of the image-sensing module before bending the flexible substrate according to the first embodiment of the instant disclosure;

FIG. 2B shows a cross-sectional view taken along the section line 2B-2B of FIG. 2A;

FIG. 2C shows a lateral, schematic view of the image-sensing module before bending the flexible substrate according to the first embodiment of the instant disclosure;

FIG. 2D shows a lateral, schematic view of the image-sensing module after bending the flexible substrate according to the first embodiment of the instant disclosure;

FIG. 3 shows a top, schematic view of the image-sensing module before bending the flexible substrate according to the second embodiment of the instant disclosure;

FIG. 4 shows a partial, cross-sectional, schematic view of the image-sensing module before bending the flexible substrate according to the third embodiment of the instant disclosure;

FIG. 5 shows a partial, cross-sectional, schematic view of the image-sensing module before bending the flexible substrate according to the fourth embodiment of the instant disclosure; and

FIG. 6 shows a partial, cross-sectional, schematic view of the image-sensing module before bending the flexible substrate according to the fifth embodiment of the instant disclosure.

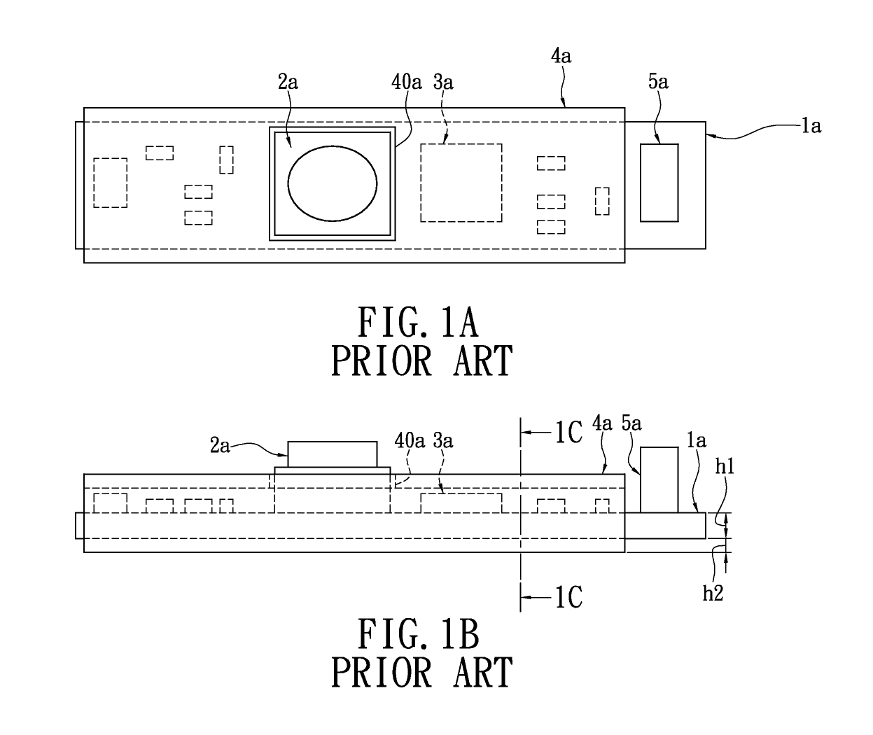

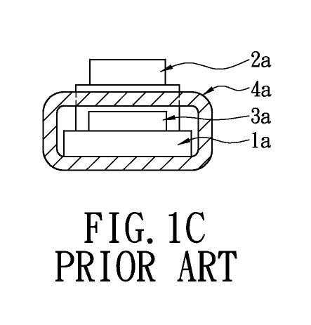

### DETAILED DESCRIPTION OF THE PREFERRED EMBODIMENTS

### First Embodiment

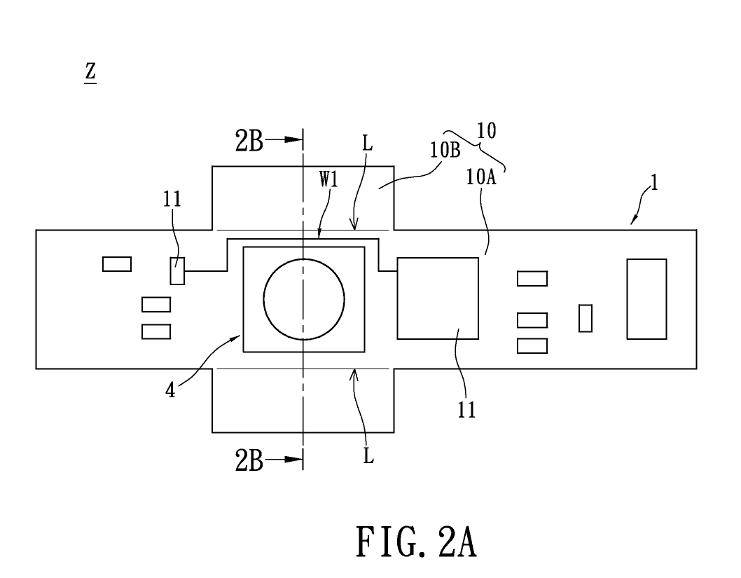

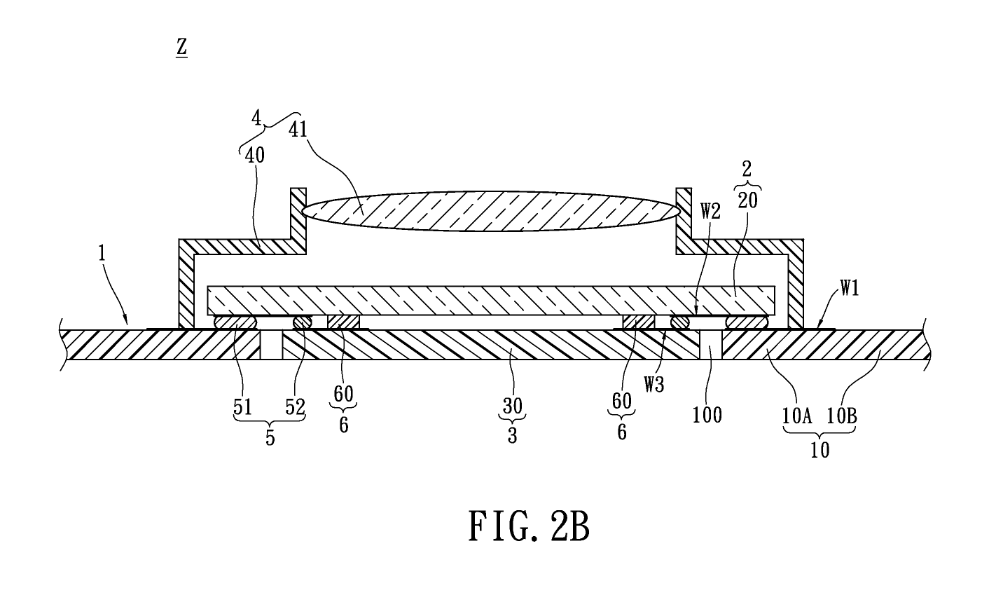

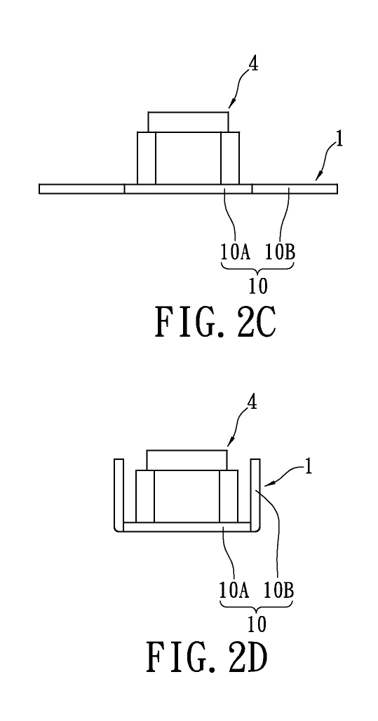

Referring to FIG. 2A to FIG. 2D, where the first embodiment of the instant disclosure provides an image-sensing module Z, comprising: a substrate unit 1, a light-transmitting unit 2, an image-sensing unit 3 and a lens unit 4.

Referring to FIG. 2A and FIG. 2B, the substrate unit 1 includes at least one flexible substrate 10, and the flexible substrate 10 has at least one through opening 100. The light-transmitting unit 2 includes at least one light-transmitting element 20 disposed on the top surface of the flexible substrate 10 and corresponding to the through opening 100. The image-sensing unit 3 includes at least one image-sensing element 30 disposed on the bottom surface of the light-transmitting element 20 and embedded in the through opening 100, where the image-sensing element 30 is electrically connected to the flexible substrate 10. The lens unit 4 includes an opaque frame 40 disposed on the top surface of the flexible substrate 10 to surround the light-transmitting element 20 and a lens 41 positioned on the opaque frame 40 to correspond to the light-transmitting element 20. For example, the flexible substrate 10 may be a flexible circuit substrate. The light-transmitting element 20 can be made of light-transmitting material or transparent material, such as glass. The image-sensing element 30 may be a sensor for capturing images, such as a CMOS (Complementary Metal-Oxide-Semiconductor) sensor, and the bottom surface of the flexible substrate 10 can be flushed with the bottom surface of the image-sensing element 30. However, the flexible substrate 10, the light-transmitting element 20 and the image-sensing element 30 used in the first embodiment are merely examples and are not meant to limit the instant disclosure.

For example, referring to FIG. 2A, FIG. 2C and FIG. 2D, when the flexible substrate 10 has not been bent yet (as shown in FIG. 2A and FIG. 2C), the flexible substrate 10 has a main portion 1 OA and at least two extending portions 10B extended outwardly from two opposite lateral sides of the main portion 10A and parallel to the main portion 10A. When the flexible substrate 10 is bent along two bending lines L as shown in FIG. 2A and FIG. 2D, the flexible substrate 10 has a main portion 10A and at least two extending portions 10B extended upwardly from two opposite lateral sides of the main portion 10A. The two extending portions 10B are respectively close to two opposite lateral sides of the lens unit 4, and the electromagnetic interference (EMI) of the instant disclosure can be reduced by using the two extending portions 10B. In addition, referring to FIG. 2A, the substrate unit 1 further includes a plurality of electronic elements 11 disposed on the flexible substrate 10, and two of the electronic elements 11 are electrically connected to each other through a first conductive track W1 only disposed on the main portion 10A. However, the substrate unit 1 used in the first embodiment is merely example and is not meant to limit the instant disclosure.

Moreover, referring to FIG. 2A and FIG. 2B, The image-sensing module Z further comprises: a conductive unit 5 including a plurality of first conductive bodies 51 disposed between the light-transmitting element 20 and the flexible substrate 10 and a plurality of second conductive bodies 52 disposed between the light-transmitting element 20 and the image-sensing element 30, and each first conductive body 51 and each second conductive body 52 may be solder balls or solder paste. Moreover, the flexible substrate 10 has at least one first conductive track W1 disposed on the top surface thereof, the light-transmitting element 20 has at least one second conductive track W2 disposed on the bottom surface thereof and electrically connected to the first conductive track W1 through one of the first conductive bodies 51, and the image-sensing element 30 has at least one third conductive track W3 disposed on the top surface thereof and electrically connected to the second conductive track W2 through one of the second conductive bodies 52, thus the image-sensing element 30 can sequentially pass through the third conductive track W3, the corresponding second conductive body 52, the second conductive track W2, the corresponding first conductive body 51 and the first conductive track W1 to electrically connect to the flexible substrate 10. Of course, the first conductive body 51 and the second conductive body 52 can be replaced by a conductive substance (not shown) connected between the first conductive track W1 of the flexible substrate 10, the second conductive track W2 of the light-transmitting element 20 and the third conductive track W3 of the image-sensing element 30 or between the first conductive track W1 of the flexible substrate 1 and the third conductive track W3 of the image-sensing element 30, thus the image-sensing element 30 can electrically connect to the flexible substrate 10 through the third conductive track W3, the conductive substance (not shown) and the first conductive track W1. However, the conductive unit 5 used in the first embodiment is merely example and is not meant to limit the instant disclosure. In other words, the image-sensing element 30 can electrically connect to the flexible substrate 10 by any connection method.

Furthermore, referring to FIG. 2A and FIG. 2B, the image-sensing module Z further comprising: a connection unit 6 including a plurality of connection elements 60 disposed between the light-transmitting element 20 and the image-sensing element 30, thus the image-sensing element 30 can be firmly fixed on the bottom surface of the light-transmitting element 20. For example, each connection element 60 may be an adhesive substance. Of course, the connection elements 60 can be replaced by a single surrounding connection element 60. However, the connection unit 6 used in the first embodiment is merely example and is not meant to limit the instant disclosure.

### Second Embodiment

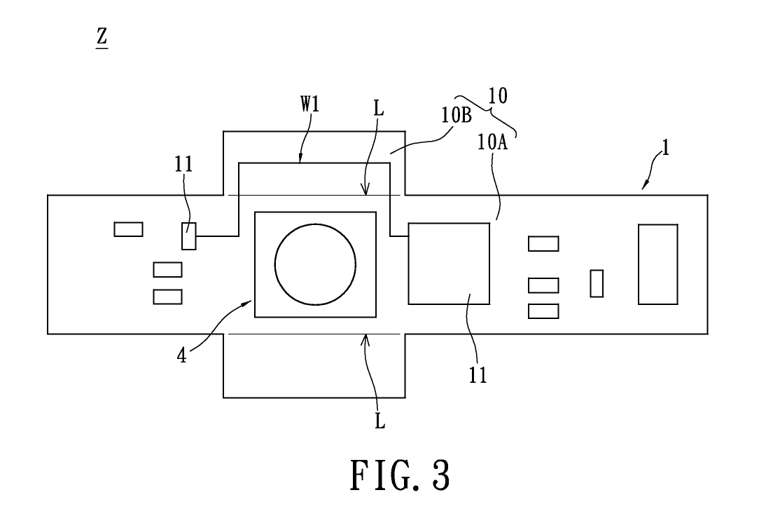

Referring to FIG. 3, where the second embodiment of the instant disclosure provides an image-sensing module Z, comprising: a substrate unit 1, a light-transmitting unit (not shown), an image-sensing unit (not shown) and a lens unit 4. Comparing FIG. 3 and FIG. 2A, the difference between the second embodiment and the first embodiment is as follows: in the second embodiment, the substrate unit 1 further includes a plurality of electronic elements 11 disposed on the flexible substrate 10, and two of the electronic elements 11 are electrically connected to each other through a first conductive track W1 simultaneously disposed on the main portion 10A and one of the two extending portions 10B. In other words, any two of the electronic elements 11 can be electrically connected to each other through the first conductive track W1 that is only disposed on the main portion 10A (as shown in the first embodiment of FIG. 2A) or is simultaneously disposed on the main portion 10A and one of the two extending portions 10B (as shown in the second embodiment of FIG. 3).

### Third Embodiment

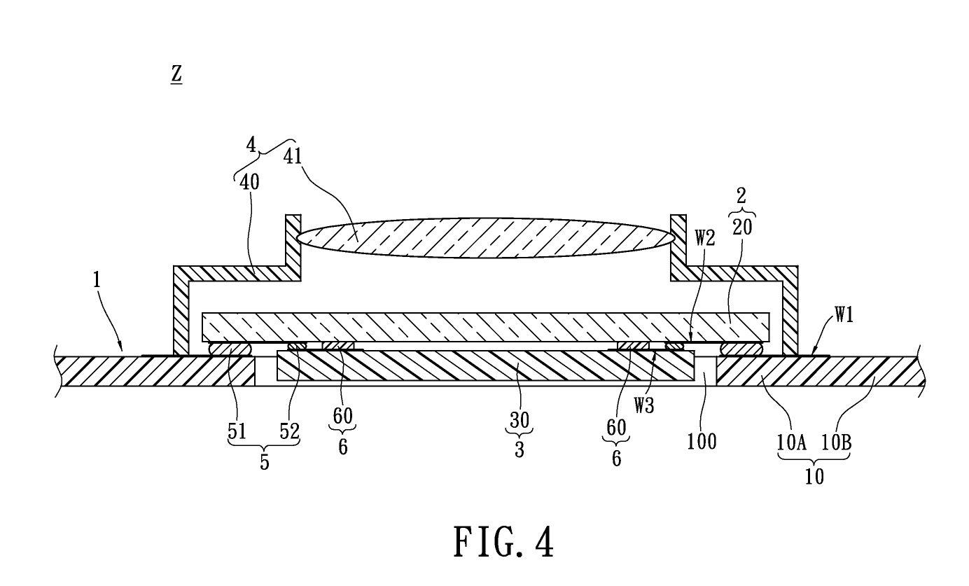

Referring to FIG. 4, where the second embodiment of the instant disclosure provides an image-sensing module Z, comprising: a substrate unit 1, a light-transmitting unit 2, an image-sensing unit 3 and a lens unit 4. The substrate unit 1 includes at least one flexible substrate 10, and the flexible substrate 10 has at least one through opening 100. The light-transmitting unit 2 includes at least one light-transmitting element 20 disposed on the top surface of the flexible substrate 10 and corresponding to the through opening 100. The image-sensing unit 3 includes at least one image-sensing element 30 disposed on the bottom surface of the light-transmitting element 20 and embedded in the through opening 100, where the image-sensing element 30 is electrically connected to the flexible substrate 10. The lens unit 4 includes an opaque frame 40 disposed on the top surface of the flexible substrate 10 to surround the light-transmitting element 20 and a lens 41 positioned on the opaque frame 40 to correspond to the light-transmitting element 20.

Comparing FIG. 4 and FIG. 2B, the difference between the third embodiment and the first embodiment is as follows: in the third embodiment, the bottom surface of the flexible substrate 10 is not flushed with the bottom surface of the image-sensing element 30. For example, the top surface of the image-sensing element 30 is convex outside the through opening 100 and the bottom surface of the image-sensing element 30 is concave inside the through opening 100, thus when the image-sensing module Z is disposed on any carrier (not shown), the image-sensing element 30 can be enclosed totally.

### Fourth Embodiment

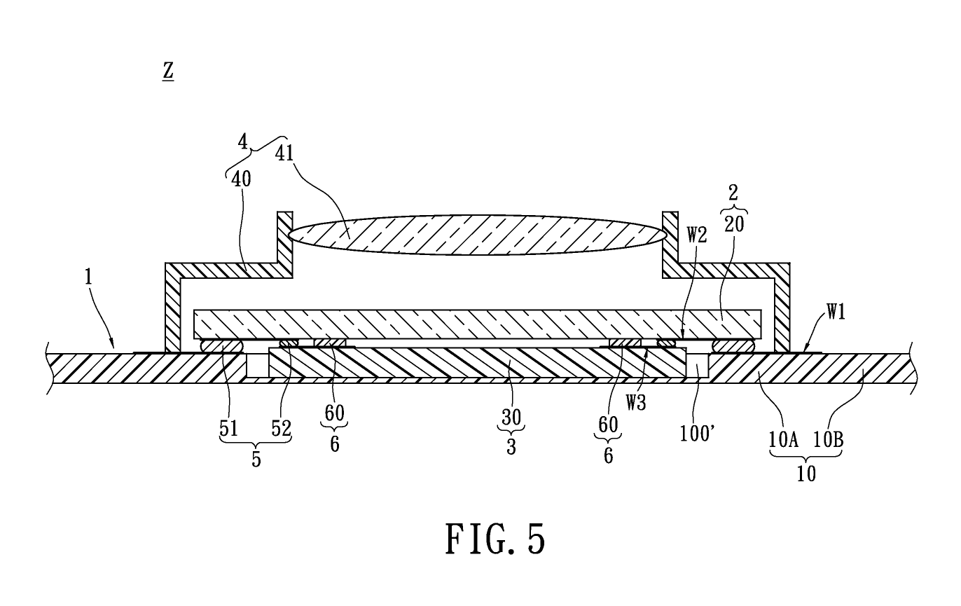

Referring to FIG. 5, where the fourth embodiment of the instant disclosure provides an image-sensing module Z, comprising: a substrate unit 1, a light-transmitting unit 2, an image-sensing unit 3 and a lens unit 4. The substrate unit 1 includes at least one flexible substrate 10, and the flexible substrate 10 has at least one receiving groove 100′. The light-transmitting unit 2 includes at least one light-transmitting element 20 disposed on the top surface of the flexible substrate 10 and corresponding to the receiving groove 100′. The image-sensing unit 3 includes at least one image-sensing element 30 disposed on the bottom surface of the light-transmitting element 20 and embedded in the receiving groove 100′, where the image-sensing element 30 is electrically connected to the flexible substrate 10. The lens unit 4 includes an opaque frame 40 disposed on the top surface of the flexible substrate 10 to surround the light-transmitting element 20 and a lens 41 positioned on the opaque frame 40 to correspond to the light-transmitting element 20.

Comparing FIG. 5 and FIG. 4, the difference between the fourth embodiment and the third embodiment is as follows: in the fourth embodiment, the through opening 100 is replaced by the receiving groove 100′, thus when the image-sensing element 30 is disposed on the bottom surface of the light-transmitting element 20 and embedded in the receiving groove 100′, the image-sensing element 30 can be enclosed totally.

### Fifth Embodiment

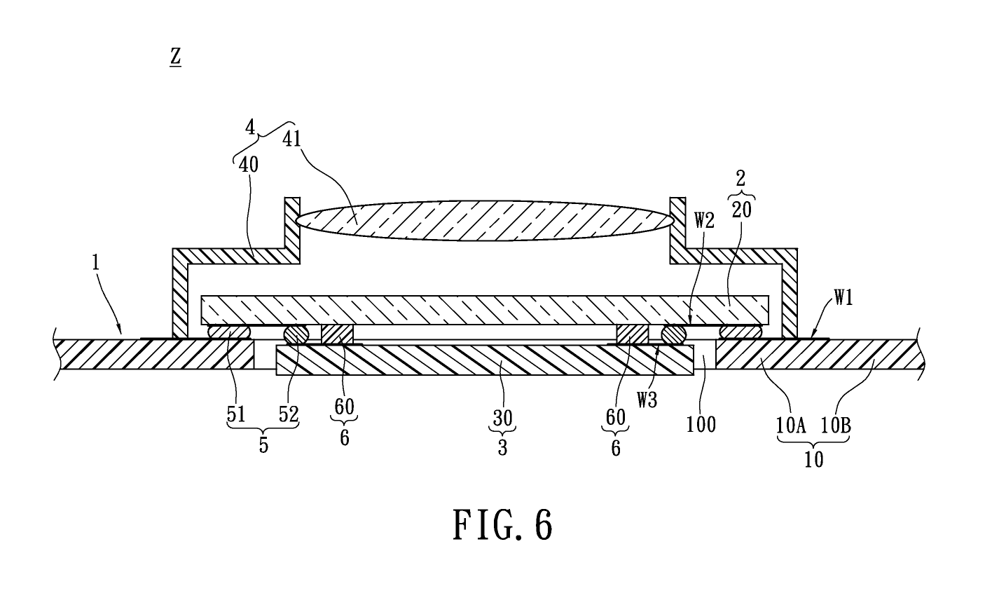

Referring to FIG. 6, where the fifth embodiment of the instant disclosure provides an image-sensing module Z, comprising: a substrate unit 1, a light-transmitting unit 2, an image-sensing unit 3 and a lens unit 4. The substrate unit 1 includes at least one flexible substrate 10, and the flexible substrate 10 has at least one through opening 100. The light-transmitting unit 2 includes at least one light-transmitting element 20 disposed on the top surface of the flexible substrate 10 and corresponding to the through opening 100. The image-sensing unit 3 includes at least one image-sensing element 30 disposed on the bottom surface of the light-transmitting element 20 and embedded in the through opening 100, where the image-sensing element 30 is electrically connected to the flexible substrate 10. The lens unit 4 includes an opaque frame 40 disposed on the top surface of the flexible substrate 10 to surround the light-transmitting element 20 and a lens 41 positioned on the opaque frame 40 to correspond to the light-transmitting element 20.

Comparing FIG. 6 and FIG. 2B, the difference between the fifth embodiment and the first embodiment is as follows: in the fifth embodiment, the bottom surface of the flexible substrate 10 is not flushed with the bottom surface of the image-sensing element 30. For example, the top surface of the image-sensing element 30 is concave inside the through opening 100 and the bottom surface of the image-sensing element 30 is convex outside the through opening 100, thus one part of the image-sensing element 30 can be exposed from the through opening 100.

In conclusion, because the at least one image-sensing element can be disposed on the bottom surface of the at least one light-transmitting element and embedded in the at least one through opening, the thickness of the image-sensing module can be reduced.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

1. An image-sensing module, comprising:
a substrate unit including at least one flexible substrate, wherein the at least one flexible substrate has a main portion and at least two extending portions respectively and upwardly extended from two opposite lateral sides of the main portion, and the main portion has at least one through opening passing therethrough;
a light-transmitting unit including at least one light-transmitting element disposed on the top surface of the at least one flexible substrate and corresponding to the at least one through opening, wherein the at least one light-transmitting element is electrically connected to the at least one flexible substrate through a plurality of first conductive bodies;
an image-sensing unit including at least one image-sensing element disposed on the bottom surface of the at least one light-transmitting element and embedded in the at least one through opening, wherein the at least one image-sensing element is electrically connected to the at least one flexible substrate through a plurality of second conductive bodies;
a lens unit including an opaque frame disposed on the top surface of the at least one flexible substrate to surround the at least one light-transmitting element and a lens positioned on the opaque frame to correspond to the at least one light-transmitting element, wherein the lens unit is disposed on the main portion and between the at least two extending portions, and the lens unit has two opposite lateral sides respectively separated from the at least two extending portions; and
a connection unit including a plurality of adhesive substances separated from the second conductive bodies and disposed between the at least one light-transmitting element and the at least one image-sensing element for firmly fixing the at least one image-sensing element on the bottom surface of the at least one light-transmitting element and exposing the at least one image-sensing element from the at least one through opening of the at least one flexible substrate.

2. (canceled)

3. The image-sensing module of claim 1, wherein the substrate unit includes a plurality of electronic elements disposed on the at least one flexible substrate, and two of the electronic elements are electrically connected to each other through a first conductive track disposed on the main portion.

4. The image-sensing module of claim 1, wherein the substrate unit includes a plurality of electronic elements disposed on the at least one flexible substrate, and two of the electronic elements are electrically connected to each other through a first conductive track simultaneously disposed on the main portion and one of the at least two extending portions.

5. The image-sensing module of claim 1, further comprising: a conductive unit including a plurality of first conductive bodies disposed between the at least one light-transmitting element and the at least one flexible substrate and a plurality of second conductive bodies disposed between the at least one light-transmitting element and the at least one image-sensing element.

6. The image-sensing module of claim 5, wherein the at least one flexible substrate has at least one first conductive track disposed on the top surface thereof, the at least one light-transmitting element has at least one second conductive track disposed on the bottom surface thereof and electrically connected to the at least one first conductive track through one of the first conductive bodies, and the at least one image-sensing element has at least one third conductive track disposed on the top surface thereof and electrically connected to the at least one second conductive track through one of the second conductive bodies.

7. (canceled)

8. The image-sensing module of claim 1, wherein the bottom surface of the at least one flexible substrate are flushed with the bottom surface of the at least one image-sensing element.

9. An image-sensing module, comprising:
a substrate unit including at least one flexible substrate, wherein the at least one flexible substrate has at least one through opening;
a light-transmitting unit including at least one light-transmitting element disposed on the top surface of the at least one flexible substrate and corresponding to the at least one through opening, wherein the at least one light-transmitting element is electrically connected to the at least one flexible substrate through a plurality of first conductive bodies;
an image-sensing unit including at least one image-sensing element disposed on the bottom surface of the at least one light-transmitting element and embedded in the at least one through opening, wherein the at least one image-sensing element is electrically connected to the at least one flexible substrate through a plurality of second conductive bodies; and
a connection unit including a plurality of adhesive substances separated from the second conductive bodies and disposed between the at least one light-transmitting element and the at least one image-sensing element for firmly fixing the at least one image-sensing element on the bottom surface of the at least one light-transmitting element and exposing the at least one image-sensing element from the at least one through opening of the at least one flexible substrate.

10. (canceled)

11. An image-sensing module, comprising:
a flexible substrate having a through opening passing therethrough;
a light-transmitting element disposed on the top surface of the flexible substrate and above the through opening, wherein the light-transmitting element is electrically connected to the flexible substrate through a plurality of first conductive bodies;
an image-sensing element disposed on the bottom surface of the light-transmitting element and disposed in the through opening, wherein the image-sensing element is electrically connected to the light-transmitting element through a plurality of second conductive bodies; and
a connection unit including a plurality of adhesive substances separated from the second conductive bodies and disposed between the light-transmitting element and the image-sensing element for firmly fixing the image-sensing element on the bottom surface of the light-transmitting element and exposing the image-sensing element from the through opening of the flexible substrate;
wherein the image-sensing element is suspended from the light-transmitting element through the adhesive substances to form an air gap between an inner surface of the though opening and the image-sensing element.
